(19) United States
(12) Patent Application Publication
(10) Pub. No.: US 2014/0342553 A1
(43) Pub. Date: Nov. 20, 2014

(54) Method for Forming Semiconductor Structure Having Opening

(71) Applicant: UNITED MICROELECTRONICS CORP., Hsin-Chu City (TW)

(72) Inventors: Chieh-Te Chen, Kaohsiung City (TW); Feng-Yi Chang, Tainan City (TW); Hsuan-Hsu Chen, Tainan City (TW); Yu-Tsung Lai, Taichung City (TW); Chih-Sen Huang, Tainan City (TW); Ching-Wen Hung, Tainan City (TW)

(73) Assignee: United Microelectronics Corp., Hsin-Chu City (TW)

(21) Appl. No.: 13/893,349

(22) Filed: May 14, 2013

(51) Int. Cl. H01L 21/768; H01L 21/283

(52) U.S. Cl. CPC H01L 21/76805; H01L 21/283; H01L 21/76877
USPC 438/666

(57) ABSTRACT

According to one embodiment of the present invention, a method for forming a semiconductor structure having an opening is provided. First, a substrate is provided, wherein a first region and a second region are defined on the substrate and an overlapping area of the first region and the second region is defined as a third region. Then, a material layer is formed on the substrate. A first hard mask and a second hard mask are formed on the material layer. The first hard mask in the first region is removed to form a patterned first hard mask. The second hard mask in the third region is removed to form a patterned second hard mask. Lastly, the material layer is patterned by using the patterned second hard mask layer as a mask to form at least an opening in the third region only.

### BACKGROUND OF THE INVENTION

1. Field of the Invention

The present invention relates to a method for forming a semiconductor structure having an opening, and more particularly, to a method that uses two lithography processes to define a first region and a second region so that the formed opening is formed in the overlapping area of the first region and the second region.

2. Description of the Prior Art

In semiconductor manufacturing processes, in order to transfer an integrated circuit layout onto a semiconductor wafer, the integrated circuit layout is first designed and formed as a photo-mask pattern. The photo-mask pattern is then proportionally transferred to a photoresist layer positioned on the semiconductor wafer.

In recent years, with the increasing miniaturization of semiconductor devices, the design rule of line width and space between lines or devices has become finer. However, the width is subject to optical characteristics. To obtain fine-sized devices in the exposure, the interval between transparent regions in a mask is scaled down with device size. When the light passes through the mask, diffraction occurs, which reduces the resolution. Moreover, when light passes through the transparent regions of a mask having different interval sizes, the light through the regions having small interval sizes is influenced by the transparent regions having large interval sizes, which results in a deformation of the transfer pattern.

A double-exposure technique has been developed in recent years. The double-exposure technique involves decomposing a target pattern into two separated patterns, which are then transferred to a photoresist layer respectively by two exposure processes. Since the pitch of the decomposed pattern is larger, the pattern can be formed by current exposure systems. However, the patterns are formed by two separated lithography processes, so the two sets of patterned may not be identical. For example, one set of patterns formed by one lithography process may be larger than another set of patterns formed by another lithography process that may be smaller. Moreover, the spacing between two set of patterns may become different. This can seriously affect the quality of devices.

### SUMMARY OF THE INVENTION

The present invention therefore provides a novel method for forming a semiconductor structure having an opening, wherein the method does not use conventional double exposure systems and wherein the drawbacks of un-identical patterns can be avoided.

According to one embodiment of the present invention, a method for forming a semiconductor structure having an opening is provided. First, a substrate is provided, wherein a first region and a second region are defined on the substrate and an overlapping area of the first region and the second region is defined as a third region. Then, a material layer is formed on the substrate. A first hard mask and a second hard mask are formed on the material layer. The first hard mask in the first region is removed to form a patterned first hard mask. The second hard mask in the third region is removed to form a patterned second hard mask. Lastly, the material layer is patterned by using the patterned second hard mask layer as a mask to form at least an opening in the third region only.

In the present invention, the opening is formed only in the overlapping region of the first region and the second region. In comparison with the conventional double-exposure technique that decomposes a target pattern into two separated patterns, the patterns formed in present invention can be more precise and identical.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 11 are schematic diagrams of the method for forming a semiconductor structure having an opening according to one embodiment of the present invention.

### DETAILED DESCRIPTION

To provide a better understanding of the presented invention, preferred embodiments will be made in detail. The preferred embodiments of the present invention are illustrated in the accompanying drawings with numbered elements.

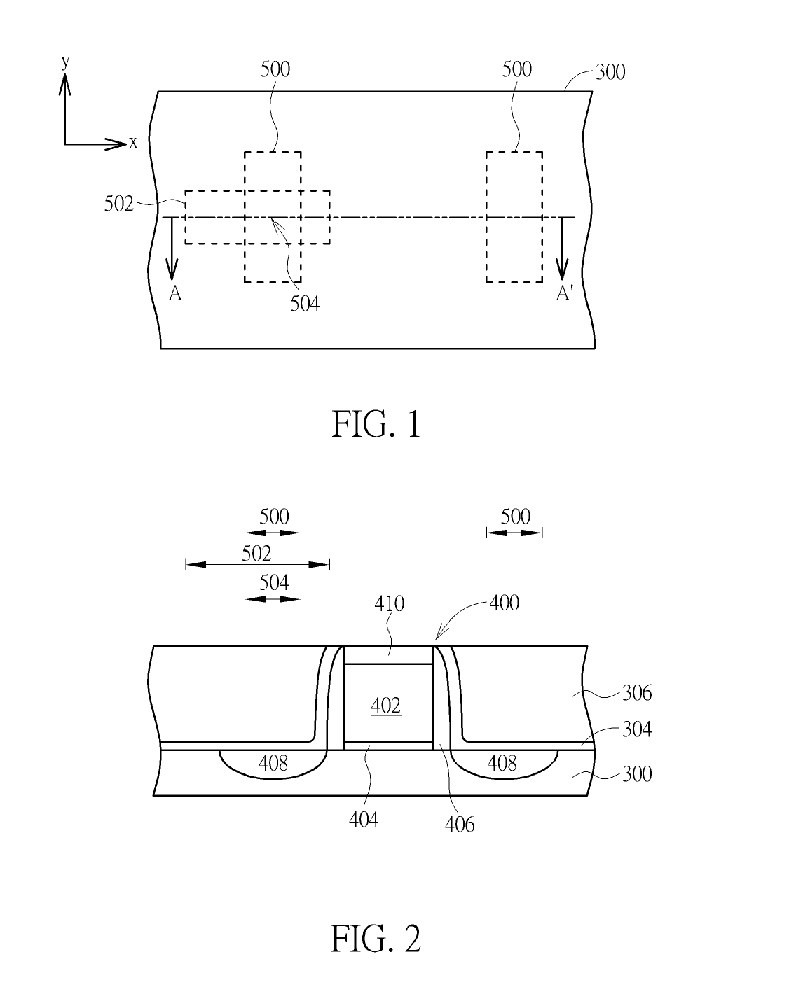

Please refer to FIG. 1 to FIG. 11, which illustrate schematic diagrams of the method for forming a semiconductor structure having an opening according to one embodiment of the present invention. FIG. 1 shows a top view and FIG. 2 to FIG. 11 show cross-sectional views taken along line AA′ in FIG. 1. As shown in FIG. 1, a substrate 300 is provided. The substrate 300 may be a silicon substrate, an epitaxial silicon substrate, a silicon germanium substrate, a silicon carbide substrate or a silicon-on-insulator (SOI) substrate, but is not limited thereto. At least a first region 500 and a second region 502 are defined on the substrate 300. In one embodiment, the first region 500 is a stripe pattern that stretches along a direction, such as the y-axis in FIG. 1, and the second region 502 is a stripe pattern that stretches along another direction, such as the x-axis in FIG. 1. The first region 500 and the second region 502 can have other shapes or have different configurations depending on the designs of the layout. A third region 504 is defined as the overlapping region of the first region 500 and the second region 502. Both the first region 500 and the second region 502 are larger than the third region 504. In the subsequent steps, an opening will be formed within the third region 504.

Then, a semiconductor device is formed on the substrate 300. The semiconductor device may be an active component such as a metal oxide semiconductor (MOS) transistor, a dynamic random access memory (DRAM), or a passive component such as an inductor, a capacitor or a resistor. The following description will use a transistor 400 as an example of semiconductor device. As shown in FIG. 2, the transistor 400 includes a gate 402 and a source/drain region 408. In one embodiment, the transistor 400 is formed by a “gate last” semiconductor manufacturing process and includes a metal gate 402. For example, a dummy gate (not shown) and a gate dielectric layer 404 are formed on the substrate 300, and then a spacer 406, a source/drain region 408, a contact etch stop layer (CESL) 304 and a first inter-dielectric (ILD) layer 306 are sequentially formed on the substrate 300. Then, the dummy gate is removed to form a trench (not shown), which is subsequently filled with metal layers to form the metal gate 402. A planarization process is performed to level a top surface of the gate 402 with the first ILD layer 306. In one embodiment, the gate 402 can contain one or a plurality of metal layers, for example, a work function metal layer, a barrier layer and a low-resistance metal layer. In one embodiment, the transistor 400 can include a sacrificial layer 410 disposed on the gate 402. For example, after the planarization process, a part of the gate 402 is removed away by an etching back process to form a recess (not shown) and a sacrificial layer 410 is formed into the recess so the sacrificial layer 410 is disposed on the gate 402 and surround by the spacer 406. Another planarization process is performed to level the sacrificial layer 410 with the first ILD layer 306. The sacrificial layer 410 preferably has an etching selectivity with respect to the first ILD layer 306. For example, when the first ILD layer 306 includes SiO₂, the sacrificial layer 410 can be SiN or SiON.

It is worth noting that each component of the transistor 400 can have different embodiments according to different designs of the devices. For example, a silicide layer (not shown) can be formed on the source/drain region 408. In another embodiment, the source/drain region 408 can contain a SiGe layer for a PMOS or a SiC layer for an NMOS, and can be formed through a selective epitaxial growth (SEG) process to further enhance the stress effect. In another embodiment, the gate dielectric layer 404 cross section has a “U” shape. In another embodiment, the transistor 400 can be any kind of planar transistors or non-planar transistors, such as a finFET, a tri-gate FET. For the sake of simplicity, those embodiments are not described in detail. It is understood that these embodiments should be also involved into the scope of the present invention.

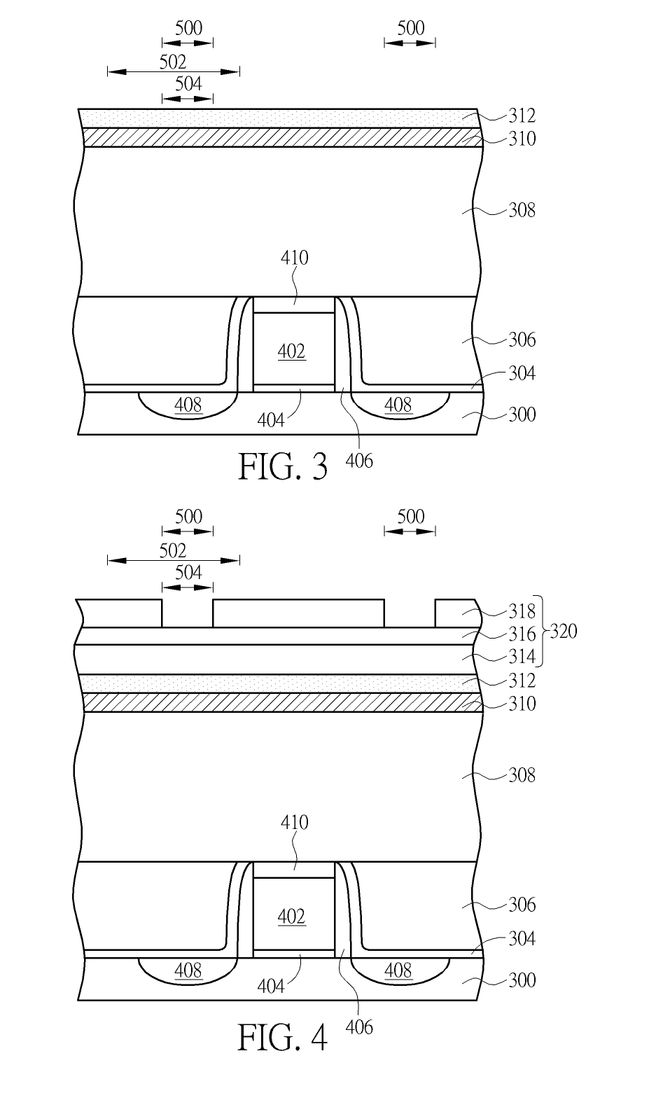

As shown in FIG. 3, a second ILD layer 308 is formed on the first ILD layer 308 and covers the transistor 400. The second ILD layer 308 can contain one or more than one dielectric layers, in which the material thereof can be the same or different from that of the first ILD layer 306, such as SiO₂, tetraethyl orthosilicate (TEOS), plasma enhanced etraethyl orthosilicate (PETEOS), but not limited thereto. The method for forming the second ILD layer 318 can include a chemical vapor deposition (CVD) process, a spin coating process, or other suitable processes that can form any dielectric materials. In another embodiment, the second ILD layer 308 can be omitted. Then, a first hard mask 312 and a second hard mask 310 are formed on the second ILD layer 308, wherein the first hard mask 312 is disposed on the second hard mask 310. The second hard mask 310 has an etching selectivity with respect to the first hard mask 312, the first ILD layer 306 and the second ILD layer 308. That is, by using the same etchant, the etching rate of the first hard mask 312 is different from that of the second hard mask 310, the first ILD layer 306 and the second ILD layer 308. The materials of the second hard mask 310, the first ILD layer 306 and the second ILD layer 308 can be the same materials or different materials. In one embodiment, the first hard mask 312 includes silicon oxide (SiO₂), silicon nitride (SiN), silicon carbide (SiC) or silicon oxynitride (SiON), and the second hard mask 310 comprises metal such as titanium (Ti), tantalum (Ta), titanium nitride (TiN), tantalum nitride (TaN) or their combinations such as Ti/TiN or Ta/TaN.

As shown in FIG. 4, a lithography process using a tri-layer photoresist 320 is performed. The tri-layer photoresist 320 contains a photoresist layer 318, an anti-reflection coating (ARC) 316 and an auxiliary mask layer 314. In one embodiment, the photoresist layer 318 is a photoresist material suitable for light source having a wavelength of 193 nm. The ARC layer 316 includes a silicon-containing hard-mask bottom anti-reflection coating (SHB) layer and the auxiliary mask layer 314 includes an organic dielectric layer (ODL) provided by Shin-Etsu Chemical Co. Ltd., wherein the SHB layer is disposed directly under the photoresist layer to serve as a BARC and a mask layer, and the ODL layer is an organic underlayer, i.e., a hydrocarbon, which is used to serve as an auxiliary mask layer. As shown in FIG. 4, the photoresist layer 318 undergoes an exposure process and a development process to remove the photoresist layer 318 in the first region 500.

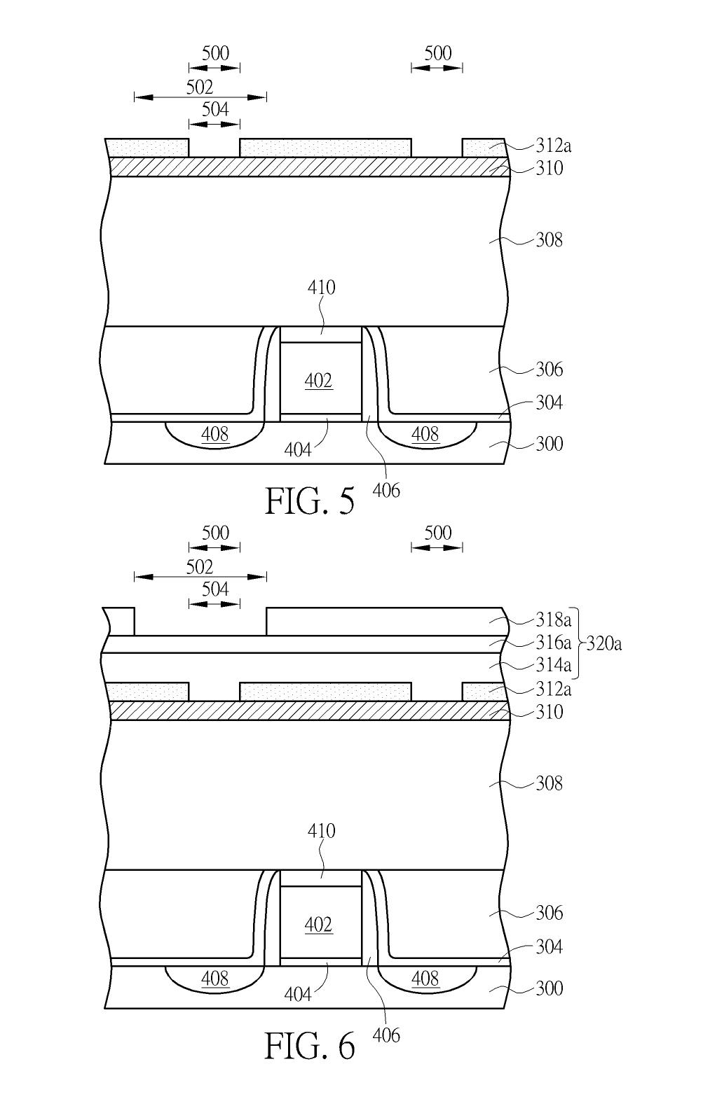

Then, as shown in FIG. 4 to FIG. 5, at least one etching process is performed by using the patterned photoresist layer 318 as a mask to sequentially pattern the ARC layer 316, the auxiliary mask layer 314, and further pattern the first hard mask 312, thereby removing the first hard mask 312 in the first region 500. A patterned first hard mask 312a having openings corresponding to the first region 500 is therefore formed. The tri-layer photoresist 320 is then removed away. It is noted that besides using the tri-layer photoresist 320, the patterned first hard mask 312a can also be formed by using other suitable photoresist materials and hard masks.

As shown in FIG. 6, another tri-layer 320a is formed on the patterned first hard mask 312a. The tri-layer 320a contains a photoresist layer 318a, an anti-reflection coating (ARC) 316a and an auxiliary mask layer 314a, wherein each layer contains a material similar to that of the tri-layer 320. Then, the photoresist layer 318a undergoes an exposure process and a development process to remove the photoresist layer 318a in the second region 502.

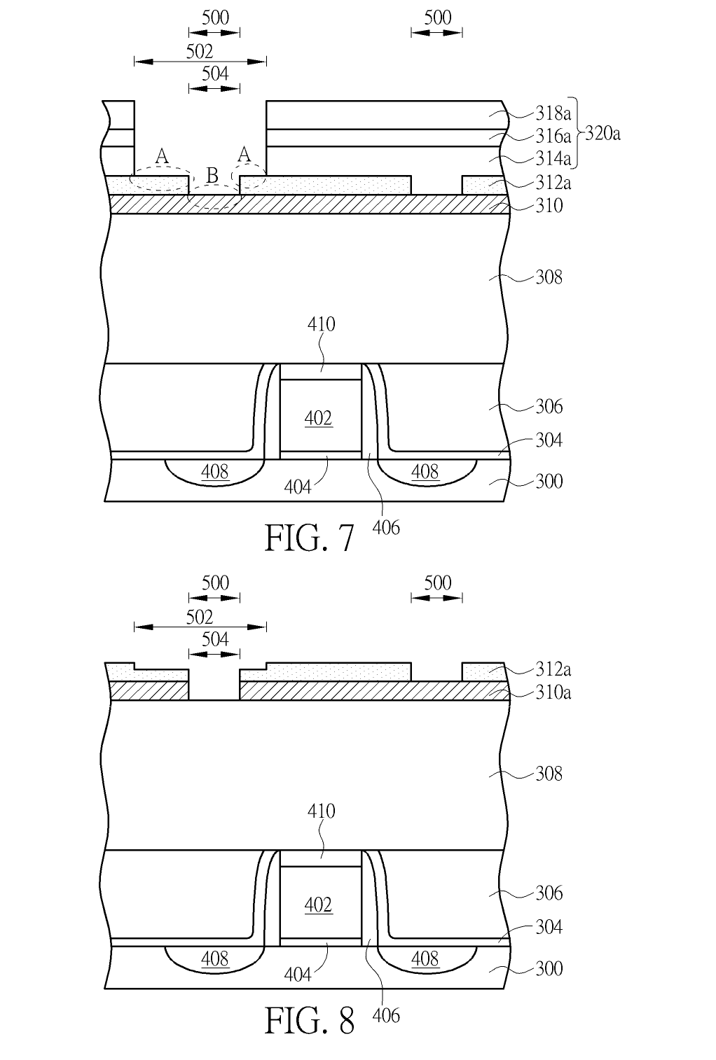

As shown in FIG. 6 to FIG. 7, at least an etching process is performed by using the patterned photoresist layer 318a as a mask to sequentially remove the ARC layer 316a, the auxiliary mask layer 314a in the second region 502, thereby exposing the patterned first hard mask 312a and the second hard mask 310.

Subsequently, as shown in FIG. 7 to FIG. 8, another etching process is performed by using both the patterned photoresist layer 318a and the patterned first hard mask 312a as a mask to pattern the second hard mask 310. Since the first hard mask 312 has an etching selectivity with respect to the second hard mask 310, during the etching process, only a small portion of patterned first hard mask 312a exposed by the tri-layer photoresist 320a is removed (area A in FIG. 7) but the second hard mask 310 exposed by the patterned first hard mask 312a will be completely removed (area B in FIG. 7). As shown in FIG. 7 in conjunction with FIG. 1, the patterned photoresist layer 318a has an opening corresponding to the second region 502 and the patterned first hard mask 312a has an opening corresponding to the first region 500; when using both the patterned photoresist layer 318a and the patterned first hard mask 312a as a mask, only the second hard mask 310 in the overlapping region of the first region 500 and the second region 502 (i.e. the third region 504) is removed away. Thereafter, as shown in FIG. 8, a patterned second hard mask 310a having an opening corresponding to the third region 504 is formed. Then, the tri-layer photoresist 320a is removed away. Besides using the tri-layer photoresist 320a, the patterned second hard mask 310a can also be formed by other conventional lithography process.

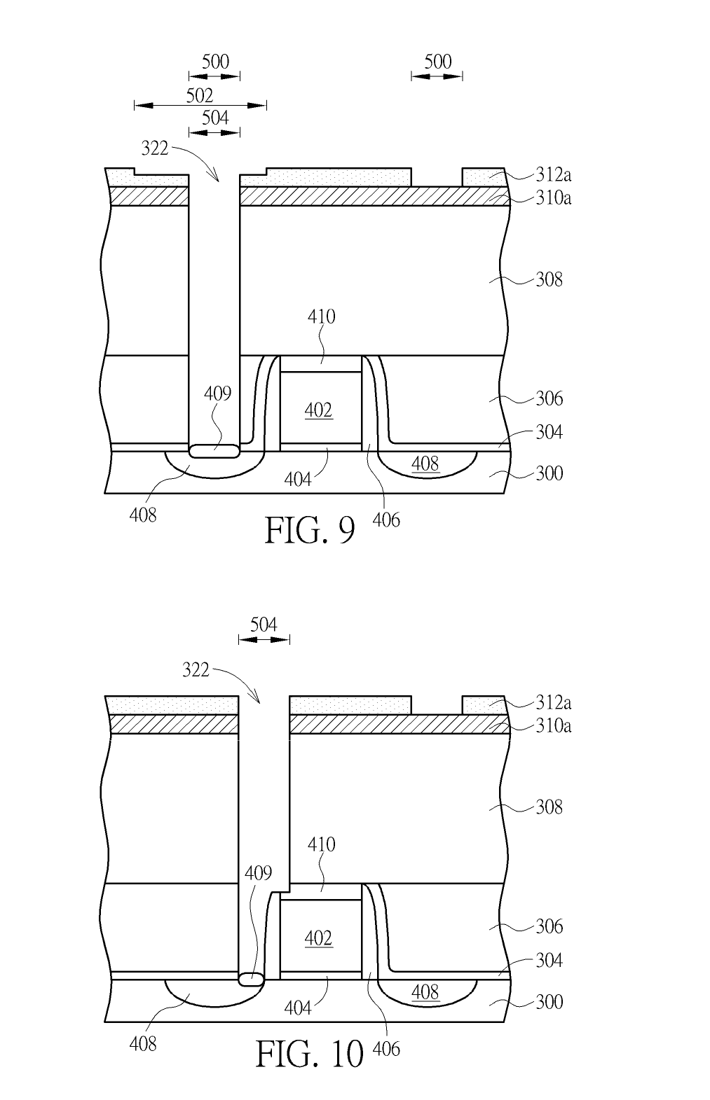

As shown in FIG. 9, at least an etching process is carried out by using the patterned second hard mask 310a as a mask to remove the second ILD layer 308 and further remove the first ILD layer 306 in the third region 504. An opening 322 is therefore formed in the first ILD layer 306 and the second ILD layer 308, wherein the opening 322 exposes the source/drain region 408 of the transistor 400. In one embodiment, when the patterned first hard mask 312a has the same material as that of the first ILD layer 306 and the second ILD layer 308, such as SiO₂, the patterned first hard mask 312a may be removed during the etching process. However, it does not affect the mask function of the patterned second hard mask 310a. In one embodiment, after forming the opening 322, a self-aligned silicide (salicide) process can be performed to form a silicide layer 409 on the source/drain region 408. The silicide layer 409 may be a nickel silicide (NiSi) layer for example.

In another embodiment, the opening 322 is used as a self align contact (SAC) to the source/drain region 408 of the transistor 400. As shown in FIG. 10, due to some manufacturing errors, the third region 504 may be shifted toward the gate 402. In the above cases, the third region 504 will not only overlap the source/drain region 408 but also extend to a part of the gate 402. In this situation, when the opening 310 is formed based on the third region 504, the gate 402 will be damaged. Accordingly, the present invention further provides a sacrificial layer 410 disposed above the gate 402. Since the sacrificial layer 410 (and preferably the spacer 406) has an etching selectivity with respect to the first ILD layer 306 and the second ILD layer 308, the etching process for forming the opening 310 will therefore stop on the sacrificial layer 410 and won't damage the gate 402. So even if the third region 504 overlaps the gate 402 and the source/drain region 408, the gate 402 is not exposed by the opening 322, and only the source/drain region 308 is exposed. That is, the opening 322 can be “self-aligned” with the source/drain region 308. Similarly, after forming the opening 322, a salicide process can be performed to form a silicide layer 409 on the source/drain region 408.

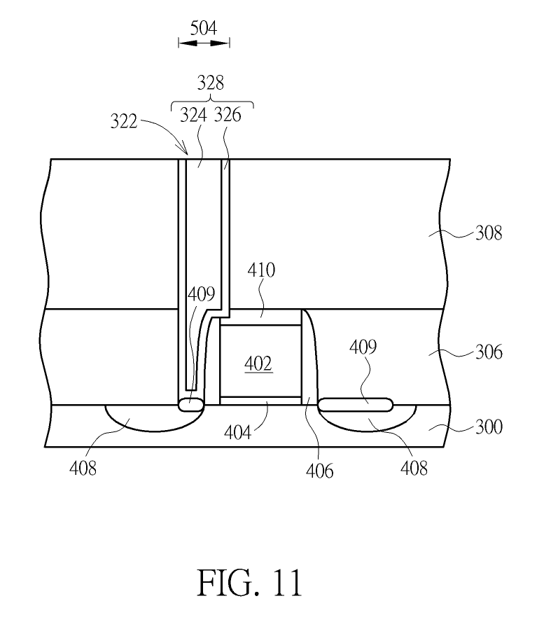

As shown in FIG. 11, after forming the opening 322, the patterned first hard mask 312a and the patterned second hard mask 310a are completely removed away. A contact plug 328 is formed in the opening 322. For instance, a barrier layer 326 and a metal layer 324 are sequentially filled into the opening 322, wherein the barrier layer 326 is formed conformally on the surface of the opening 322, and the metal layer 324 completely fills the opening 322. In one embodiment, the barrier layer 326 can include titanium (Ti), titanium nitride (TiN) or tantalum nitride (TaN) or a plurality of metal layers such as Ti/TiO, but not limited thereto. The metal layer 324 can include a variety of low-resistance metal materials, such as aluminum (Al), titanium (Ti), tantalum (Ta), tungsten (W), niobium (Nb), molybdenum (Mo), copper (Cu) or the likes, preferably tungsten or copper, and most preferably tungsten, which can form suitable Ohmic contacts between the metal layer 324 and the silicide layer 409 or the source/drain region 408 below. Thereafter, a planarization step, such as a chemical mechanical polish (CMP) process or an etching back process or a combination thereof, can be performed to remove the metal layer 314 and the barrier layer 312 outside the opening 310. A contact plug 328 is therefore formed in the opening 322.

In summary, the present invention provides a method for forming a semiconductor structure having an opening. As shown in FIG. 1, the opening is formed only in the overlapping area of the first region and the second region. Comparing to conventional arts, the double-exposure technique decomposes a target pattern into two separated patterns, so the assembling of the two patterns will be the final pattern on the wafer. However, in the present invention, only the overlapping area of the two regions will be the final pattern on the wafer. Since the final pattern is defined both by the first region and the second region, the drawback in conventional double-exposure technique such as un-identical patterns and unequal spacing can be avoided. The patterns formed in present invention can be more precise and identical. It is understood that the opening formed by the present invention can be used not only as a contact plug of a transistor but also of any semiconductor structure and can be applied in any related fields such as optical devices or micro-electro-mechanical systems (MEMS).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming a semiconductor structure having an opening, comprising:
providing a substrate, wherein a first region and a second region are defined on the substrate and an overlapping area of the first region and the second region is defined as a third region;
forming a material layer on the substrate;
forming a first hard mask and a second hard mask on the material layer, wherein the first hard mask is disposed on the second hard mask;
removing the first hard mask in the first region to form a patterned first hard mask;
removing the second hard mask in the third region to form a patterned second hard mask; and
patterning the material layer by using the patterned second hard mask layer as a mask, to form at least an opening only in the third region.

2. The method for forming a semiconductor structure having an opening as in claim 1, wherein the step of forming the patterned first hard mask comprises:
forming a first photoresist layer on the first hard mask;
performing a first lithography process to remove the first photoresist layer in the first region; and
performing a first etching process to remove the first hard mask in the first region by using the patterned first photoresist layer as a mask to form the patterned first hard mask.

3. The method for forming a semiconductor structure having an opening as in claim 2, wherein after forming the patterned first hard mask, the patterned first hard mask exposes the second hard mask.

4. The method for forming a semiconductor structure having an opening as in claim 1, further comprising forming an ARC and a mask layer between the first mask layer and the first photoresist layer.

5. The method for forming a semiconductor structure having an opening as in claim 1, wherein the step of forming the patterned second hard mask comprises:
forming a second photoresist layer on the patterned first hard mask;
performing a second lithography process to remove the second photoresist layer in the second region; and
performing a second etching process to remove the second hard mask in the third region by using the patterned second photoresist layer and the patterned first hard mask as a mask, to form the patterned second hard mask.

6. The method for forming a semiconductor structure having an opening as in claim 5, wherein in the second etching process, only the second hard mask in the third region is removed.

7. The method for forming a semiconductor structure having an opening as in claim 5, further comprising forming an ARC and a mask layer between the second mask layer and the second photoresist layer.

8. The method for forming a semiconductor structure having an opening as in claim 1, wherein after forming the patterned second hard mask, further comprising completely removing the patterned first hard mask.

9. The method for forming a semiconductor structure having an opening as in claim 1, wherein the first hard mask has an etching selectivity with respect to the second hard mask.

10. The method for forming a semiconductor structure having an opening as in claim 1, the first hard mask comprises silicon oxide, silicon nitride, silicon carbide or silicon oxynitride, and the second hard mask comprises Ti/TiN or Ta/TaN.

11. The method for forming a semiconductor structure having an opening as in claim 1, before forming the material layer, further comprising forming a transistor on the substrate.

12. The method for forming a semiconductor structure having an opening as in claim 11, the transistor comprises a gate and a source/drain region on the substrate, wherein the source/drain region overlaps the third region.

13. The method for forming a semiconductor structure having an opening as in claim 11, wherein the material layer is an inter-dielectric (ILD) layer.

14. The method for forming a semiconductor structure having an opening as in claim 11, wherein after patterning the material layer, the source/drain region of the transistor is exposed by the opening.

15. The method for forming a semiconductor structure having an opening as in claim 14, after exposing the source/drain region of the transistor, further comprising filling a conductive layer in the opening, and the conductive layer in the contact hole becomes a contact plug.

16. The method for forming a semiconductor structure having an opening as in claim 12, wherein the transistor further comprises a sacrificial layer disposed on the gate.

17. The method for forming a semiconductor structure having an opening as in claim 16, wherein the sacrificial layer has an etching selectively with respect to the material layer.

18. The method for forming a semiconductor structure having an opening as in claim 16, wherein after patterning the material layer, the source/drain region of the transistor and the sacrificial layer are exposed by the opening.

19. The method for forming a semiconductor structure having an opening as in claim 16, wherein after patterning the material layer, the gate below the sacrificial layer is not exposed.

20. The method for forming a semiconductor structure having an opening as in claim 18, after exposing the source/drain region of the transistor and the sacrificial layer, further comprising filling a conductive layer in the opening, so the conductive layer in the opening becomes a contact plug.
